(19) United States
(12) Patent Application Publication
(10) Pub. No.: US 2006/0134852 A1
(43) Pub. Date: Jun. 22, 2006

(54) Interconnect and head gimbal assembly with the same

(75) Inventor: Eun-kyu Jang, Daegu Metropolitan City (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 11/260,290

(22) Filed: Oct. 28, 2005

(30) Foreign Application Priority Data
Dec. 21, 2004 (KR) 10-2004-0109286

(51) Int. Cl. H01L 21/8238

(52) U.S. Cl. 438/232

(57) ABSTRACT

An interconnect for connecting a magnetic head slider and a flexible printed circuit, and a head gimbal assembly having the interconnect are provided. The interconnect includes a ground layer, a first insulation layer formed on the ground layer, and a pair of signal transferring layers formed on the first insulation layer and spaced apart from each other, in which the ground layer has an outer ground layer portion formed at an outside of the pair of signal transferring layers and not superposed on the pair of signal transferring layers, and an inner ground layer portion formed between the pair of the signal transferring layers.

### CROSS REFERENCE TO RELATED APPLICATIONS

This application claims the benefit of Korean Patent Application No. 10-2004-109286, filed on Dec. 21, 2004, in the Korean Intellectual Property Office, the disclosure of which is incorporated herein in its entirety by reference.

### BACKGROUND OF THE INVENTION

1. Field of the Invention

The present invention relates to a head gimbal assembly for a hard disk drive, and more particularly, to an improved interconnect capable of decreasing impedance and radiation of electromagnetic waves, and a head gimbal assembly having the same for use in a hard disk drive.

2. Description of the Related Art

A hard disk drive is an auxiliary memory unit for a personal computer, etc. to read data from a disk or write data on the disk, by use of a magnetic head mounted to a magnetic head slider. During operation of the hard disk drive, the magnetic head slider is floated at a certain interval relative to the disk. The magnetic head reads the data from the disk or writes the data on the disk.

The data read from the disk by the magnetic head is converted into an electrical signal, referred to as a read signal, and is then transferred from the magnetic head slider to a main circuit board of the hard disk drive through a flexible printed circuit. On the other hand, an electrical signal corresponding to the data to be recorded on the disk, referred to as a write signal, is transferred from the main circuit board to the magnetic head slider through the flexible printed circuit.

In general, the read signal and the write signal are transferred between the magnetic head slider and the flexible printed circuit through an interconnect. FIGS. 1 and 2 are cross-sectional views illustrating first and second examples of a conventional interconnect.

Referring to FIG. 1, a conventional interconnect 10 includes a ground layer 11, a first insulation layer 13 formed on the ground layer 11, a pair of signal transferring layers 15a and 15b formed on the first insulation layer 13, and a second insulation layer 17 sealing the signal transferring layers 15a and 15b. The pair of signal transferring layers 15a and 15b are spaced apart from each other to prevent a short circuit. Referring to FIG. 2, another conventional interconnect 20 includes a ground layer 21, first and second insulation layers 23 and 27, and a pair of signal transferring layers 25a and 25b, similar to the above interconnect 10. However, a portion of the ground layer 21 positioned under the signal transferring layers 25a and 25b is removed, so that the signal transferring layers 25a and 25b are not superposed on the ground layer 21.

FIG. 3 is a graph illustrating a relationship between a frequency and size of the signal for the interconnects 10 and 20 shown in FIGS. 1 and 2.

Referring to FIG. 3, when signals of the same frequency and size are inputted to the interconnects 10 and 20, respectively, a signal at an output of the interconnect 10 has a size smaller than that of the interconnect 20. It would be appreciated that attenuation of the signal at the output of the interconnect 10 is larger than that of the interconnect 20. In addition, the higher the frequency is, the more the attenuation of the signal gradually increases.

It would be appreciated from FIG. 3 that the interconnect 20 with a portion of the ground layer removed has an improved performance relative to that of the interconnect 10, in terms of the attenuation of the signal. However, there is a disadvantage in that the impedance of the interconnect 20 is higher than that of the interconnect 10. For this reason, the interconnect 10 is used as an interconnect for transferring the read signal to which a frequency band of about 1 GHz is transferred, while the interconnect 20 is used as an interconnect for transferring the write signal to which a relatively high frequency, i.e., a frequency band of up to 10 GHz is transferred. The impedance of the interconnect 20 is decreased by enlarging a width of the signal transferring layers 25a and 25b of the interconnect 20.

In the case where the width of the signal transferring layer is enlarged, the width of the interconnect itself becomes large. In view of the tendency to gradually miniaturize the size of the hard disk drive, the method of enlarging the width of the signal transferring layer may not be employed, and thus comes up to a structural limit.

### SUMMARY OF THE INVENTION

Additional aspects and/or advantages of the invention will be set forth in part in the description which follows and, in part, will be apparent from the description, or may be learned by practice of the invention.

The present invention provides an interconnect capable of reducing attenuation of a signal and decreasing impedance, and a head gimbal assembly with the interconnect.

The present invention also provides an interconnect capable of decreasing impedance without enlarging a width of a signal transferring layer relative to a conventional interconnect, and a head gimbal assembly with the interconnect.

According to an aspect of the present invention, there is provided an interconnect connected to a magnetic head slider of a hard disk drive for transferring a signal, including: a ground layer; a first insulation layer formed on the ground layer; and a pair of signal transferring layers formed on the first insulation layer and spaced apart from each other, in which the ground layer has an outer ground layer portion formed at an outside of the pair of signal transferring layers and not superposed on the pair of signal transferring layers, and an inner ground layer portion formed between the pair of the signal transferring layers.

The interconnect may further include a second insulation layer sealing the pair of signal transferring layers.

The interconnect may further include a bridge layer portion interconnecting the inner ground layer portion and the outer ground layer portion.

According to another aspect of the present invention, there is provided a head gimbal assembly including a suspension, a magnetic head slider attached to and supported by the suspension, and an interconnect connected to the magnetic head slider for transferring a signal, the interconnect including: a ground layer; a first insulation layer formed on the ground layer; and a pair of signal transferring layers formed on the first insulation layer and spaced apart from each other, in which the ground layer has an outer ground layer portion formed at an outside of the pair of signal transferring layers and not superposed on the pair of signal transferring layers, and an inner ground layer portion formed between the pair of the signal transferring layers.

The head gimbal assembly may further include a second insulation layer sealing the pair of signal transferring layers.

The head gimbal assembly may further include a bridge layer portion interconnecting the inner ground layer portion and the outer ground layer portion.

The interconnect may transfer a write signal to the magnetic head slider.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are cross-sectional views illustrating examples of a conventional interconnect;

FIG. 3 is a graph illustrating a relationship between a frequency and size of a signal for the interconencts shown in FIGS. 1 and 2;

FIG. 4 is a plan view illustrating one example of a hard disk drive;

FIG. 5 is a perspective view of a head gimbal assembly according to an embodiment of the present invention;

FIG. 6 is an enlarged cross-sectional view of an interconnect provided to the head gimbal assembly shown in FIG. 5; and

FIG. 7 is an enlarged plan view of a ground layer provided to the interconnect shown in FIG. 6.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

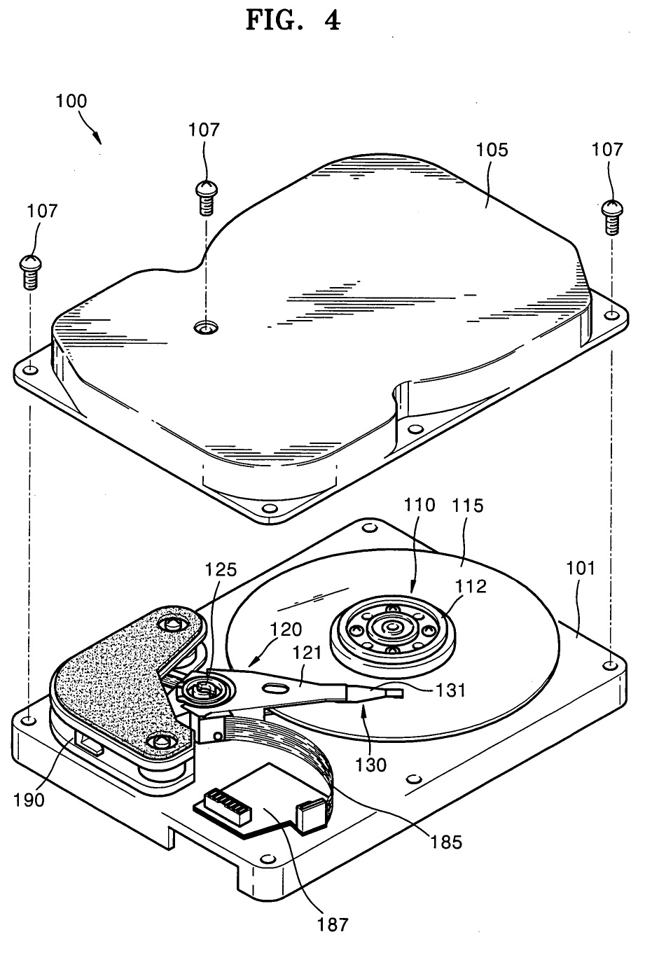

FIG. 4 is a plan view illustrating one example of a hard disk drive 100. Referring to FIG. 4, the hard disk drive 100 includes a housing consisting of a base plate 101 and a cover plate 105 engaged to the base plate by screws 107. The housing accommodates a spindle motor 110, a disk 115, an actuator 120, and a voice coil motor 190.

The spindle motor 110 is fixed to the base plate 101 to turn the disk 115. The disk 115 is fixed to a rotator (not shown) of the spindle motor 110 to rotate with rotation of the rotator. A disk clamp 112 is engaged to an upper end of the spindle motor 110 to prevent the disk 115 from being released.

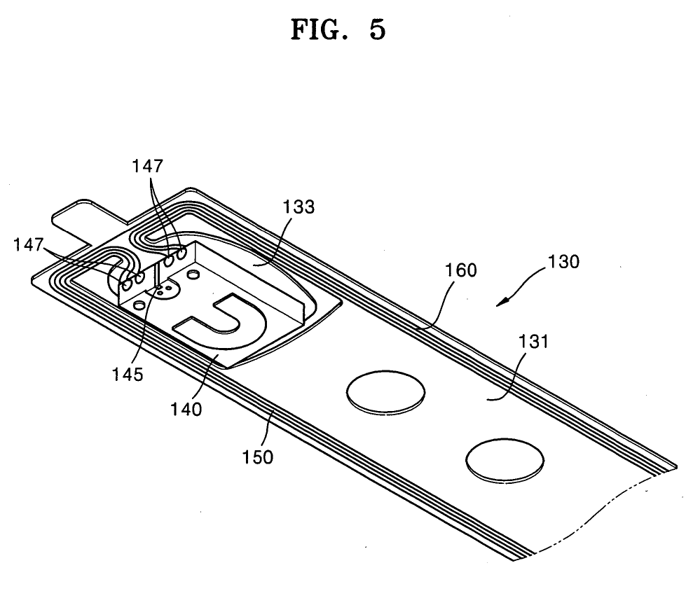

The actuator 120 is mounted with the magnetic head slider 140 (FIG. 5), and transfers the magnetic head slider 140 to a desired position to write data on the disk 115 or read the data from the disk 115. The actuator 120 includes a head gimbal assembly 130 and a swing arm 121. The swing arm 121 is pivotally engaged to the pivot shaft 125 installed on the base plate 101. The head gimbal assembly 130 includes a suspension 131 fixed to a front end of the swing arm 121. The magnetic head slider 140 is attached to and supported by a front end of the suspension 131. The suspension 131 resiliently urges the magnetic slider 140 towards a surface of the disk 115.

The voice coil motor 190 fixed to the base plate 101 supplies a rotational force to the actuator 120. Although not shown in the accompanying drawings, the voice coil motor 190 includes a magnet and a yoke, which are disposed at upper and lower portions of the coil of the actuator 120, respectively. The voice coil motor 190 is controlled by a servo control system, and rotates the actuator 120 in a direction according to Fleming's left-hand rule due to interaction of magnetic field defined by the magnet and current applied to the coil.

The base plate 101 is provided at one corner thereof with a bracket 187 for connecting a flexible printed circuit 185 which is connected to the actuator 120 to a main circuit board disposed under the base plate 101. Although not shown in the accompanying drawings, at the other corner diagonally opposite to the one corner, a circulation filter for filtering foreign substances, such as particles, contained in air flowing in the hard disk drive 100 is provided to an inside of the cover plate 105.

If a power is applied to the hard disk drive 100, the disk 115 is turned at high speed, and the magnetic head slider 140 (FIG. 5) supported by the suspension 131 is floated from the surface of the disk 115 at a certain height by balance of a lift force produced from flow of the air induced by the rotation of the disk 115 and an urging force of the suspension 131 towards the surface of the disk 115. In this state, the actuator 120 moves the magnetic head slider 140 to a certain position on the disk 115 to write the data on the disk 115 or read the data from the disk 115.

FIG. 5 is a perspective view of the head gimbal assembly 130 according to an embodiment of the present invention.

Referring to FIG. 5, the suspension 131 is provided at the front end thereof with a mounting portion 133 for mounting and supporting the magnetic head slider 140. The mounting portion 133 is isolated from a periphery region by etching or the like, except for a portion of the mounting portion to be connected to the magnetic head slider. As a result, smooth rolling and pitching of the magnetic head slider 140 is possible.

The magnetic head slider 140 is provided with a magnetic head 145 with a lower end facing the disk 115 (FIG. 4). A lead (not shown) of the magnetic head 145 is electrically connected to one end of a write signal transferring interconnect 150 for transferring a write signal and another lead (not shown) is electrically connected to one end of a read signal transferring interconnect 160 for transferring read signal via bonding balls 147. The other ends of the interconnects 150 and 160 are connected to the flexible printed circuit 185 (FIG. 4). With the above construction, the read signal is transferred from the magnetic head 145 to the main circuit board through the interconnect 160 and the flexible printed circuit board 185. The write signal is transferred from the main circuit board to the magnetic head 145 through flexible printed circuit 185 and the interconnect 150.

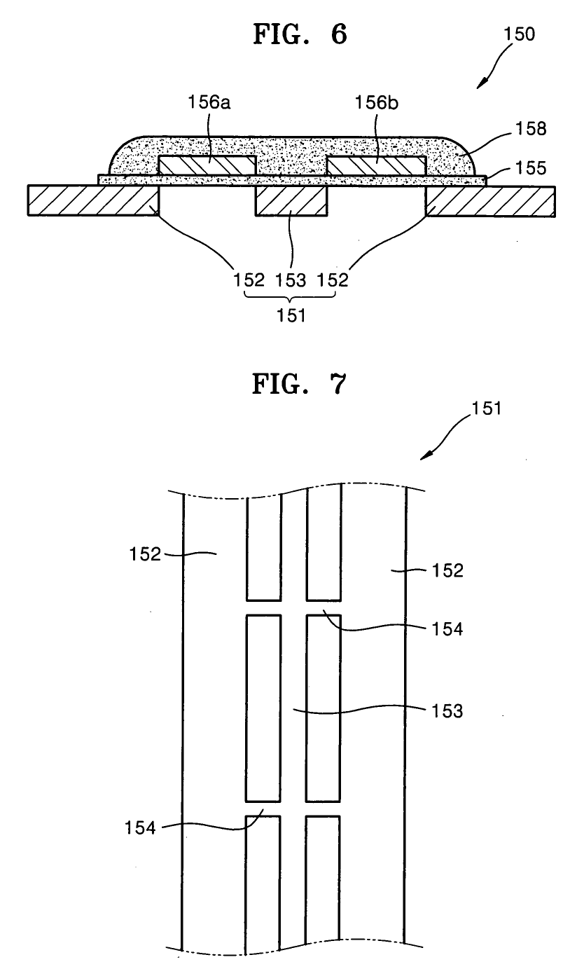

FIG. 6 is an enlarged cross-sectional view of the interconnects for transferring write and read signals provided to the head gimbal assembly shown in FIG. 5.

Referring to FIG. 6, the interconnect 150 for transferring the write signal includes a ground layer 151, a first insulation layer 155 formed on the ground layer 151, a pair of signal transferring layers 156a and 156b formed on the first insulation layer 155, and a second insulation layer 158 sealing the signal transferring layers 156a and 156b. The pair of signal transferring layers 156a and 156b are spaced apart from each other to prevent a short circuit. The signal transferring layers 156a and 156b may be made of copper. The signal transferring layers 156a and 156b may have a width of 70 μm, a thickness of 18 μm, and a spacing of 40 μm therebetween, respectively. The first and second insulation layers 155 and 158 may be made of polyimide.

A portion of the ground layer 151 positioned under the pair of signal transferring layers 156a and 156b is removed, so that the signal transferring layers are not superposed on the ground layer 151. The ground layer 151 has an outer ground layer portion 152 formed at an outside of the pair of the signal transferring layers 156a and 156b, and an inner ground layer portion 153 formed between the pair of the signal transferring layers 156a and 156b, which is different from the conventional interconnect in FIG. 2.

Referring to FIG. 7, the ground layer 151 also has a bridge layer portion 154 for interconnecting the inner ground layer portion 153 and the outer ground layer portion 152. The ground layer 151 may be made of stainless steel, and have a thickness of 20 μm.

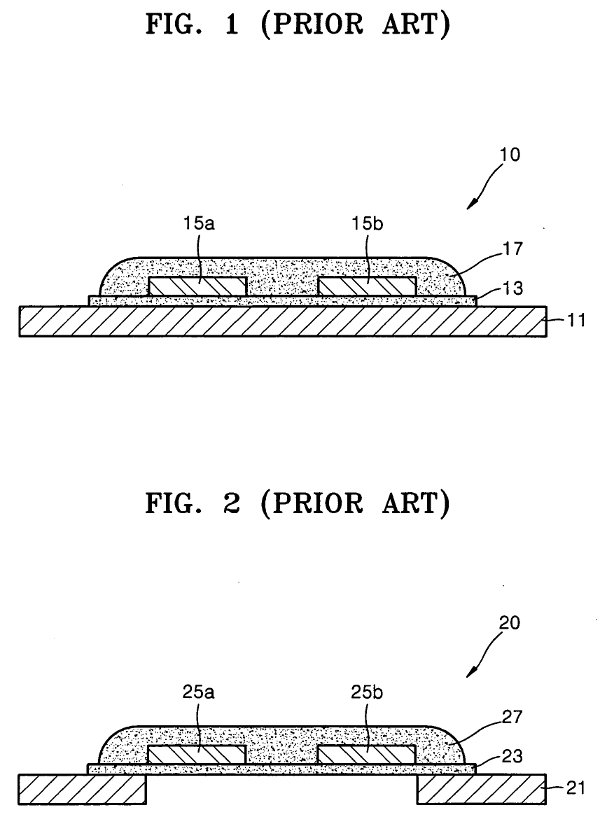

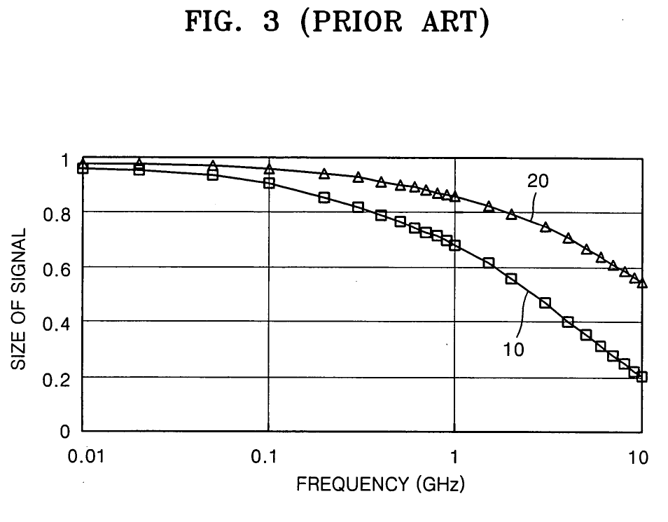

With the interconnect 150 shown in FIG. 6, since the ground layer 151 disposed under the signal transferring layers 156a and 156b is removed, a loss due to an eddy current is decreased relative to that of the interconnect 10 shown in FIG. 1. Accordingly, the interconnect 150 has a characteristic of a signal attenuation similar to the interconnect 20 shown in FIG. 2.

Meanwhile, impedance of the interconnect tends to decrease as the ground layer is close to the signal transferring layer. The interconnect 150 shown in FIG. 6 has the inner ground layer portion 153, and thus a distance between the ground layer 151 and the signal transferring layers 156a and 156b is substantially more shorter than the interconnect 20 shown in FIG. 2. Accordingly, the impedance is decreased relative to the interconnect 20 shown in FIG. 2.

Also, in the interconnect 150, a coupling of electric field is formed between an edge of the outer ground layer 152 and edges of the signal transferring layers 156a and 156b adjacent to the outer ground layer 152, and an edge of the inner ground layer 153 and the edges of the signal transferring layers 156a and 156b adjacent to the outer ground layer 153, which suppresses external radiation of the electric field. Accordingly, electromagnetic interference (EMI) due to the radiation of electromagnetic waves is decreased relative to the interconnect 20 shown in FIG. 2.

The interconnect of the present invention and the head gimbal assembly with the same have a characteristic of good signal attenuation. Also, the impedance of the interconnect decreases relative to a conventional interconnect. Therefore, since it is not necessary to enlarge a width of the signal transferring layer to decrease the impedance of the interconnect, the interconnect and the head gimbal assembly may be miniaturized, and thus the hard disk drive may be also miniaturized.

Furthermore, the electromagnetic interference due to the radiation of the electromagnetic waver may be decreased relative to the conventional interconnect.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An interconnect connected to a magnetic head slider of a hard disk drive for transferring a signal, comprising:
a ground layer;
a first insulation layer formed on the ground layer; and
a pair of signal transferring layers formed on the first insulation layer and spaced apart from each other,
wherein the ground layer has an outer ground layer portion formed at an outside of the pair of signal transferring layers and an inner ground layer portion formed between the pair of the signal transferring layers.

2. The interconnect according to claim 1, further comprising a second insulation layer sealing the pair of signal transferring layers.

3. The interconnect according to claim 1, further comprising a bridge layer portion interconnecting the inner ground layer portion and the outer ground layer portion.

4. The interconnect according to claim 1, wherein the pair of signal transferring layers are made of copper.

5. The interconnect according to claim 1, wherein the pair of signal transferring layers have a width of 70 μm, a thickness of 18 μm, and a spacing of 40 μm therebetween.

6. The interconnect according to claim 2, wherein the first and second insulation layers are made of polyimide.

7. The interconnect according to claim 1, wherein the ground layer is made of stainless steel.

8. The interconnect according to claim 1, wherein the ground layer has a thickness of 20 μm.

9. A head gimbal assembly including a suspension, a magnetic head slider attached to and supported by the suspension, and an interconnect connected to the magnetic head slider transferring a signal, the interconnect comprising:
a ground layer;
a first insulation layer formed on the ground layer; and
a pair of signal transferring layers formed on the first insulation layer and spaced apart from each other,
wherein the ground layer has an outer ground layer portion formed at an outside of the pair of signal transferring layers and an inner ground layer portion formed between the pair of the signal transferring layers.

10. The head gimbal assembly according to claim 9, further comprising a second insulation layer sealing the pair of signal transferring layers.

11. The head gimbal assembly according to claim 9, further comprising a bridge layer portion interconnecting the inner ground layer portion and the outer ground layer portion.

12. The head gimbal assembly according to claim 9, wherein the interconnect is to transfer a write signal to the magnetic head slider.

13. The head gimbal assembly according to claim 9, wherein the pair of signal transferring layers are made of copper.

14. The head gimbal assembly according to claim 9, wherein the pair of signal transferring layers have a width of 70 μm, a thickness of 18 μm , and a spacing of 40 μm therebetween.

15. The head gimbal assembly according to claim 10, wherein the first and second insulation layers are made of polyimide.

16. The head gimbal assembly according to claim 9, wherein the ground layer is made of stainless steel.

17. The head gimbal assembly according to claim 9, wherein the ground layer has a thickness of 20 μm.
